(19) United States
(12) Patent Application Publication
(10) Pub. No.: US 2012/0064374 A1
(43) Pub. Date: Mar. 15, 2012

(54) Dot-Patterned Structure, Magnetic Recording Medium, and Method for Production Thereof

(76) Inventor: Yoshiharu Kanegae, Hitachinaka (JP)

(21) Appl. No.: 13/301,212

(22) Filed: Nov. 21, 2011

Related U.S. Application Data
(63) Continuation of application No. 12/249,183, filed on Oct. 10, 2008, now abandoned.

(30) Foreign Application Priority Data
Oct. 16, 2007 (JP) 2007-269235

(51) Int. Cl. G11B 5/66; B32B 3/00; G03F 7/20

(52) U.S. Cl. 428/827; 430/325; 430/320; 428/141; 428/831.2

(57) ABSTRACT

Disclosed herein are a dot-patterned structure for magnetic recording bits and a magnetic recording medium provided therewith. The former exhibits high functionality and high performance owing to good crystallinity. The dot-patterned structure is composed of a first layer, which is continuous, and a second layer, which is discrete. The magnetic recording medium having a dot-patterned recording layer is formed by the steps of treating an underlying layer by lithography, thereby forming grooves, filling the grooves by epitaxial growth with the same material as the underlying layer, removing the photoresist used for lithography in a solvent, thereby forming pits, and filling the pits by epitaxial growth with a magnetic film as the recording layer.

### CROSS REFERENCE TO RELATED APPLICATION

This application is a continuation of U.S. application Ser. No. 12/249,183, filed Oct. 10, 2008, the contents of which are incorporated herein by reference.

### BACKGROUND OF THE INVENTION

1. Field of the Invention

The present invention relates to a dot-patterned structure, a magnetic recording medium, and a method for production thereof.

2. Description of the Related Art

An increased recording density for recording media is essential for high-speed, high-capacity, and low-cost magnetic recording units such as HDD. An HDD is designed to store information (data) by means of magnetization of magnetic particles in a magnetic thin film as a recording layer. Magnetic particles have to be smaller for the recording layer to have a higher recording density. However, the size reduction of magnetic particles is limited for the conventional magnetic recording media of longitudinal recording type, because excessively small magnetic particles greatly decrease in thermal stability, which disturbs the direction of magnetization and causes recorded information to disappear. It seems that such a limit is approaching now.

One way of solving this problem is by recent development of perpendicular recording media, as disclosed in Non-Patent Document 1. Perpendicular recording media are highly resistant to thermal fluctuation and permit the bit intervals to be reduced more. Therefore, they are expected to achieve a higher recording density than that which the longitudinal recording media would achieve by size reduction of magnetic particles. Unfortunately, the current perpendicular recording media use a thin magnetic film as the recording film in the same way as the conventional longitudinal recording media. Consequently, they still have problems with bit-to-bit variation and noise in reproduced signals.

In order to best solve these problems, there has been proposed a magnetic recording medium called patterned media, as disclosed in Non-Patent Document 2. It has, in place of a recording layer, magnetic particles in uniform size and shape formed by microfabrication and arranged in an array of dots on a disk. On the other hand, the magnetic film (as the recording layer of the magnetic recording medium) should have good crystallinity so that its easy axis of magnetization orients in the horizontal or vertical direction with respect to the substrate surface. Good crystallinity is important for the magnetic layer as well as the underlying layer thereof. Therefore, the patterned medium, which has magnetic particles arranged in an array of dots as its recording layer, should rely on a process capable of forming the dot-patterned structure without mechanical damage due to etching or die imprinting which adversely affects the crystallinity of the recording film and underlying film.

### Non-Patent Document 1:

Y. Hosoe, “Jiki Kiroku Baitai” (Magnetic Recording Media), The 28th Summer School of the Magnetic Society of Japan, “Ouyou Jiki no Kiso” (Fundamentals of Applied Magnetism), (2004. 7. 13-15), pp. 1-13.

### Non-Patent Document 2:

S. Y. Chou et al.: J. Appl. Phys. 76, 6673 (1994)

### SUMMARY OF THE INVENTION

It is an object of the present invention to provide a dot-patterned structure consisting of a first layer, which is continuous, and a second layer, which is discrete, both layers having a good crystalline structure. It is another object of the present invention to provide a magnetic recording medium with a dot-patterned structure and a process for production thereof, the magnetic recording medium having a recording film and an underlying film, both having a good crystallinity. It is another object of the present invention to provide a magnetic recording unit with high functionality and high reliability.

A first aspect of the present invention is directed to a dot-patterned structure which is composed of a first layer, which is continuous, and a second layer, which is discrete. The first layer is formed by treating by lithography a thin film having a crystalline structure, thereby forming grooves therein, and filling the grooves with the same material as the thin film in such a way that the filled grooves become integral with the thin film. The second layer is formed by removing the photoresist used for lithography, thereby forming pits, and filling the pits with a material different from that of the thin film.

A second aspect of the present invention is also directed to a method for producing the dot-patterned structure which is composed of a first layer, which is continuous, and a second layer, which is discrete. The method includes the steps of treating by lithography a thin film having a crystalline structure, thereby forming grooves in the thin film, filling the grooves with the same material as the thin film, thereby forming the first layer, removing the photoresist used for lithography, thereby forming pits, and filling the pits with a material different from that of the thin film, thereby forming the second layer, which is discrete.

A third aspect of the present invention is directed to a magnetic recording medium which is composed of a substrate, an underlying layer, and a magnetic film as the recording layer, which are arranged sequentially on top of the other, the magnetic film being formed by the steps of forming grooves by lithography in the underlying layer, filling the grooves with the same material as the underlying layer, and filling pits which remain after removal of the photoresist used for lithography.

A fourth aspect of the present invention is directed also to a method for producing a magnetic recording medium having a substrate and an underlying layer thereon, the method including the steps of forming grooves by lithography in the underlying layer, filling the grooves with the same material as the underlying layer, removing the photoresist used for lithography, thereby forming pits, and filling the pits with a magnetic film as the recording layer.

A fifth aspect of the present invention is directed also to a magnetic recording medium which is composed of a substrate, a soft magnetic layer, an underlying layer, and a magnetic film as the recording layer, which are arranged sequentially on top of the other, the magnetic film being formed by the steps of forming grooves by lithography in the underlying layer, filling the grooves with the same material as the underlying layer, and filling pits which remain after removal of the photoresist used for lithography.

A sixth aspect of the present invention is directed also to a method for producing a magnetic recording medium, the method including the steps of coating a substrate with a soft magnetic layer and an underlying layer sequentially, treating the underlying layer by lithography to form grooves therein, filling the grooves with the same material as the underlying layer, removing the photoresist used for lithography, thereby forming pits, and filling the pits with a magnetic film as the recording layer.

The dot-patterned structure according to the aspects of the present invention is composed of a first layer, which is continuous, and a second layer placed thereon, which is discrete. In the magnetic recording medium according to the present invention, the first layer corresponds to the underlying layer of the recording layer, and the second layer corresponds to the magnetic film of the recording layer.

In the dot-patterned structure according to the aspects of the present invention, the grooves formed in the first layer by lithography should preferably be filled by epitaxial growth with the same material as the first layer. In the magnetic recording medium according to the present invention, the grooves formed in the underlying layer by lithography should preferably be filled by epitaxial growth with the same material as the underlying layer.

It is also desirable that the pits formed by removing in a solvent the photoresist used for lithography should be filled by epitaxial growth with the material of the second layer or the recording layer.

The present inventors reviewed magnetic recording media from the standpoint of their constituting materials and their manufacturing method. The result of their review is that the following process gives rise a magnetic recording medium with high functionality and high reliability. The process includes the steps of treating the underlying layer by lithography, thereby forming grooves, filling the grooves by epitaxial growth with the same material as the underlying layer, removing in a solvent the photoresist used for lithography, thereby forming pits, and finally filling the pits by epitaxial growth a magnetic film for the recording layer. The magnetic film for the recording layer as well as the underlying layer have good crystallinity.

The foregoing process is best carried out if the underlying layer is formed from a material containing Cr, W, Mo, or the like (having the body-centered cubic structure) for the longitudinal magnetic recording medium or a material containing Ru, Os, Re, or the like (having the hexagonal close-packed structure) for the vertical magnetic recording medium. These materials have a larger close-packed atomic distance and a larger Young's modulus than such magnetic elements as Fe, Co, Ni, and the like which are used for the recording layer. With this structure, the magnetic layer should be under tensile strain so that the magnetic atoms have a larger magnetic moment than in their unstrained state or compressed strain state. This causes the recording layer to improve in thermal stability and increase in reproduced signals.

The aspects of the present invention makes it possible to produce a magnetic recording medium and a dot-patterned structure which have good crystallinity, good thermal stability, and uniform magnetic recording bits.

### BRIEF DESCRIPTION OF THE DRAWINGS

Embodiment(s) of the present invention will be described in detail based on the following figures, wherein:

FIG. 1 is a sectional view showing the magnetic recording medium according to the first embodiment;

FIG. 2 is a sectional view showing another magnetic recording medium according to the first embodiment;

FIG. 3 is a sectional view showing further another magnetic recording medium according to the first embodiment;

FIG. 4 is a diagram showing the first step for producing the magnetic recording medium constructed as shown in FIG. 2;

FIG. 5 is a diagram showing the second step for producing the magnetic recording medium constructed as shown in FIG. 2;

FIG. 6 is a diagram showing the third step for producing the magnetic recording medium constructed as shown in FIG. 2;

FIG. 7 is a diagram showing the fourth step for producing the magnetic recording medium constructed as shown in FIG. 2;

FIG. 8 is a sectional view showing the magnetic recording medium according to the second embodiment;

FIG. 9 is a sectional view showing another magnetic recording medium according to the second embodiment;

FIG. 10 is a sectional view showing further another magnetic recording medium according to the second embodiment;

FIG. 11 is a sectional view showing further another magnetic recording medium according to the second embodiment;

FIG. 12 is a diagram showing the first step for producing the magnetic recording medium constructed as shown in FIG. 9;

FIG. 13 is a diagram showing the second step for producing the magnetic recording medium constructed as shown in FIG. 9;

FIG. 14 is a diagram showing the third step for producing the magnetic recording medium constructed as shown in FIG. 9; and

FIG. 15 is a diagram showing the fourth step for producing the magnetic recording medium constructed as shown in FIG. 9.

### DESCRIPTION OF THE PREFERRED EMBODIMENTS

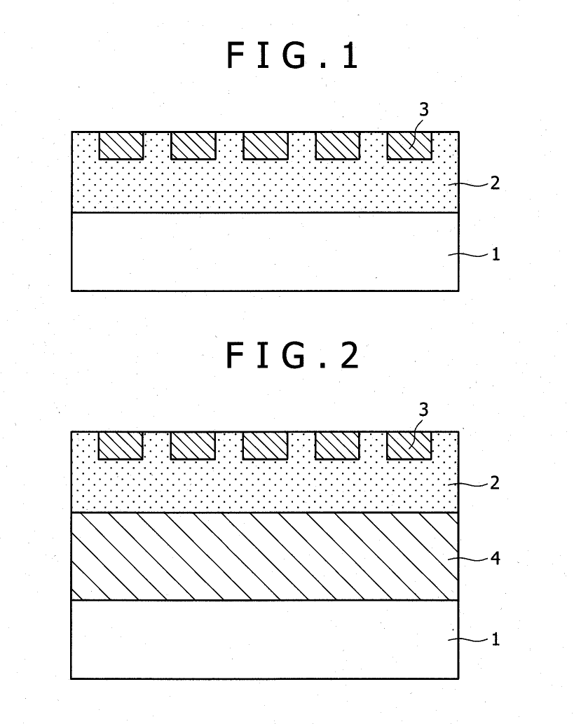

The embodiments of the present invention will be described below with reference to FIGS. 1 to 15.

FIG. 1 is a sectional view showing the magnetic recording medium according to the first embodiment. The magnetic recording medium is composed of a substrate 1, an underlying layer 2, and a dot-patterned recording layer 3, which are arranged sequentially on top of the other. The dot-patterned recording layer 3 should preferably be one which is formed by the steps of forming grooves on the underlying layer 2 by photolithography, filling the grooves with the same material as the underlying layer 2, and finally forming a magnetic film as the recording layer 3. In this way there are obtained the underlying layer and the magnetic film, both of which have good crystallinity with a minimum of mechanical damage.

The substrate 1 may be a glass substrate, aluminum substrate, or aluminum alloy substrate, for example. The recording layer 3 is formed from a magnetic alloy (such as CoCrPt), a granular magnetic alloy containing an oxide (such as CoCrPt—SiO₂), or these materials containing additional elements. The underlying layer 2 should preferably be formed from a material which contains Cr, W, Mo, or the like, has the body-centered cubic structure, and also has a larger close-packed atomic distance and a larger Young's modulus than the magnetic element (such as Co) of the recording layer. The recording layer 3 should be composed of magnetic atoms whose axis of easy magnetization is oriented in the horizontal direction with respect to the substrate, and the magnetic layer should be under tensile strain so that the magnetic atoms have a larger magnetic moment than in their unstrained state or compressed strain state.

The magnetic recording medium according to this embodiment may also be composed of a substrate 1, a seed layer 4, an underlying layer 2, and a dot-patterned recording layer 3, which are arranged sequentially on top of the other, as shown in FIG. 2. The seed layer 4 helps the (100) plane of the body-centered cubic structure of the underlying layer 2 to grow more easily parallel to the substrate. It also facilitates orientation (in the horizontal direction with respect of the substrate) of the easy axis of magnetization of magnetic atoms in the magnetic layer on the underlying layer 2. The seed layer 4 is formed from a Ni alloy such as Ni—P, for example.

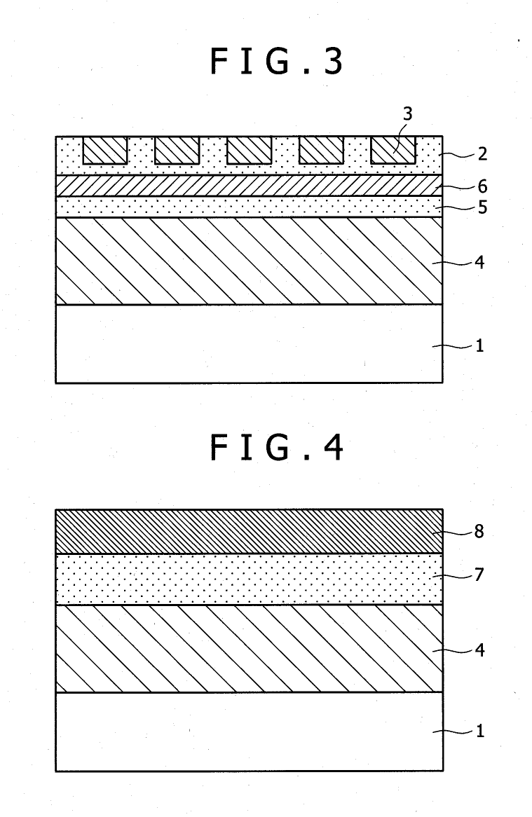

The magnetic recording medium according to this embodiment may also be composed of a substrate 1, a seed layer 4, an underlying layer 5, a stabilizing layer 6 of magnetic material, an underlying layer 2, and a dot-patterned recording layer 3, which are arranged sequentially on top of the other, as shown in FIG. 3. The underlying layer 2 functions as a magnetic coupling layer, which produces anti-ferromagnetic coupling between the magnetic moment of the stabilizing layer 6 and the magnetic moment of the recording layer 3. This imparts good thermal stability to the magnetic recording medium. The underlying layer 5 may be coated with stabilizing layers and magnetic coupling layers of non-magnetic material which are laminated alternately.

The magnetic recording medium shown in FIG. 2 is produced by the process which is explained below with reference to FIGS. 4 to 7.

First, the substrate 1 is coated with the seed layer 4 by plating, sputtering or CVD (chemical vapor deposition). On the seed layer 4 is formed the underlying layer 7 by epitaxial growth. The underlying layer 7 is coated with the photoresist 8 for patterning.

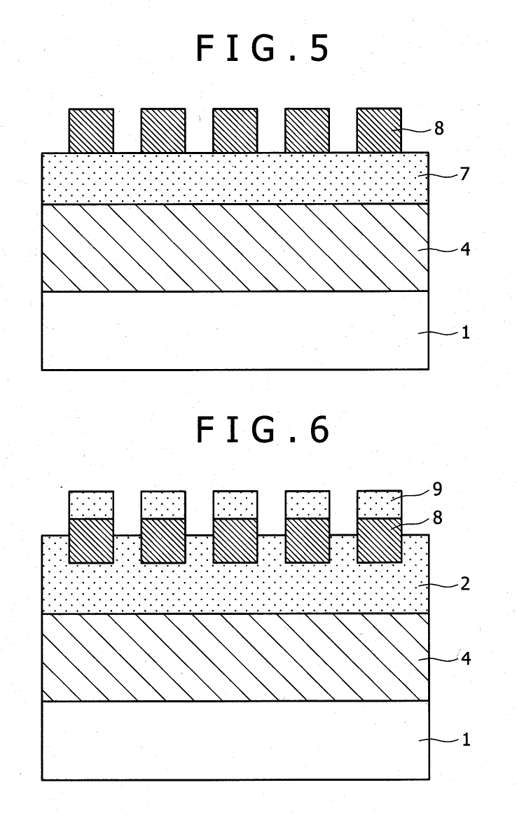

The photoresist 8 undergoes photolithography and subsequent development to form grooves, as shown in FIG. 5.

The thus formed grooves are filled with the same material as the underlying layer 7 by epitaxial growth, as shown in FIG. 6. The filling material and the underlying layer 7 become integral to form the underlying layer 2.

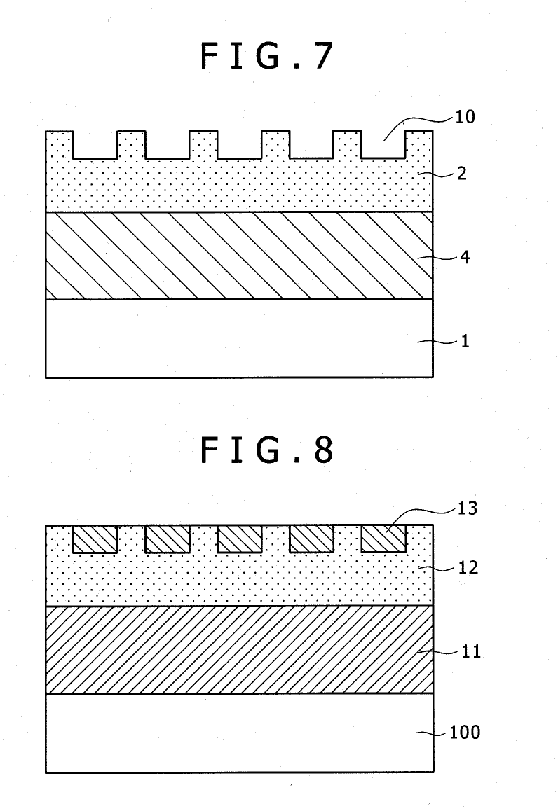

The photoresist 8 and the material 9 deposited thereon are removed all at once by dipping in a solvent such as acetone. This step forms the pits 10 (to be filled with a magnetic material), as shown in FIG. 7.

The pits 10 are filled with a magnetic material, and this step is followed by CMP (chemical mechanical polishing) for planarizing. In this way there is obtained the magnetic recording medium shown in FIG. 2.

In practical process, however, the magnetic recording medium shown in FIG. 2 is coated with an overcoat (containing carbon) and a lubricating film sequentially. Such additional films are omitted in this embodiment.

The magnetic recording medium produced by the above-mentioned steps has a recording layer and an underlying layer, both of which are superior in crystallinity and thermal stability, and also has fairly uniform magnetic recording bits.

FIG. 8 is a sectional view showing the magnetic recording medium according to the second embodiment. The magnetic recording medium is composed of a substrate 100, a soft magnetic layer 11, an underlying layer 12, and a dot-patterned recording layer 13, which are arranged sequentially on top of the other. The dot-patterned recording layer 13 should preferably be formed by the steps of forming pits in the underlying layer 12 by photolithography, filling them with the same material as the underlying layer 12, and finally forming a magnetic film as the recording layer 13. In this way there are obtained the underlying layer and the magnetic film, both of which have good crystallinity with a minimum of mechanical damage.

The substrate 100 may be a glass substrate, aluminum substrate, or aluminum alloy substrate, for example. The soft magnetic layer 11 is formed from iron alloy, nickel alloy, cobalt alloy, or the like, such as NiFe, FeTaC, and CoTaZr. The recording layer 13 is formed from a magnetic alloy (such as CoCrPt), a granular magnetic alloy containing an oxide (such as CoCrPt—SiO₂), or these materials containing additional elements. The underlying layer 12 should preferably be formed from a material which contains Ru, Os, Re, or the like, has the hexagonal close packed structure, and also has a larger close-packed atomic distance and a larger Young's modulus than the magnetic element (such as Co) of the recording layer. The recording layer 13 should be composed of magnetic atoms whose axis of easy magnetization is oriented in the vertical direction with respect to the substrate, and the magnetic layer should be under tensile strain so that the magnetic atoms have a larger magnetic moment than in their unstrained state or compressed strain state.

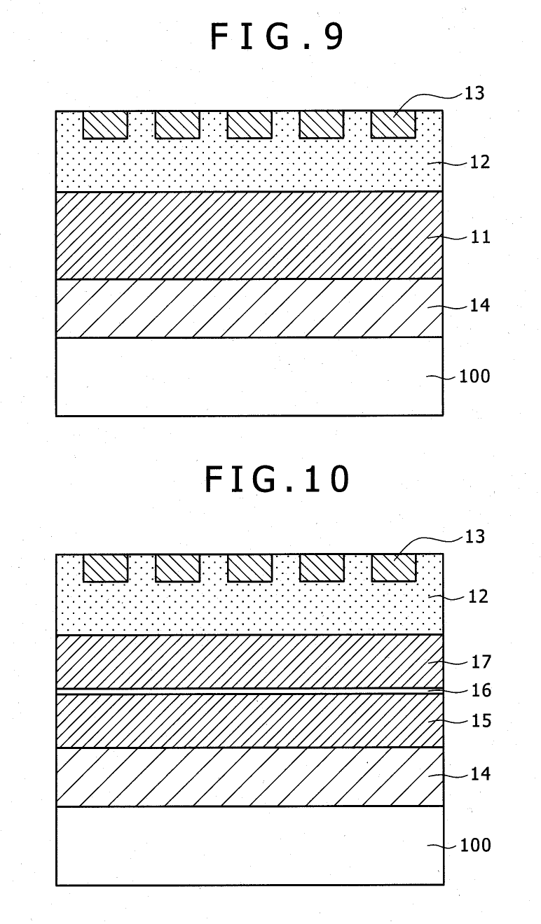

The magnetic recording medium according to this embodiment may be modified as shown in FIG. 9. The modified one is composed of the substrate 100, the precoat layer 14, the soft magnetic layer 11, the underlying layer 12, and the dot-patterned recording layer 13, which are arranged sequentially on top of the other.

The precoat layer 14 should preferably be formed from such alloy as NiTa and NiTaZr, if the substrate 100 is a glass substrate. However, if the substrate is an aluminum alloy substrate, it should preferably be formed from an aluminum alloy differing in composition from the aluminum alloy for the substrate. The precoat layer 14 improves adhesion to the substrate 100.

The magnetic recording medium according to this embodiment may be modified as shown in FIG. 10. The modified one is composed of the substrate 100, the precoat layer 14, the first soft magnetic layer 15, the magnetic coupling layer 16, the second soft magnetic layer 17, the underlying layer 12, and the dot-patterned recording layer 13, which are arranged sequentially on top of the other.

The advantage of this modification is a reduction of magnetic noise from the soft magnetic layers on account of anti-ferromagnetic coupling that occurs between the magnetic moment of the first soft magnetic layer 15 and the magnetic moment of the second soft magnetic layer 17.

The magnetic coupling layer 16 is formed from a non-magnetic material containing Ru, Os, Re, or the like. The precoat layer 14 may be coated with soft magnetic layers and magnetic coupling layers which are alternately laminated.

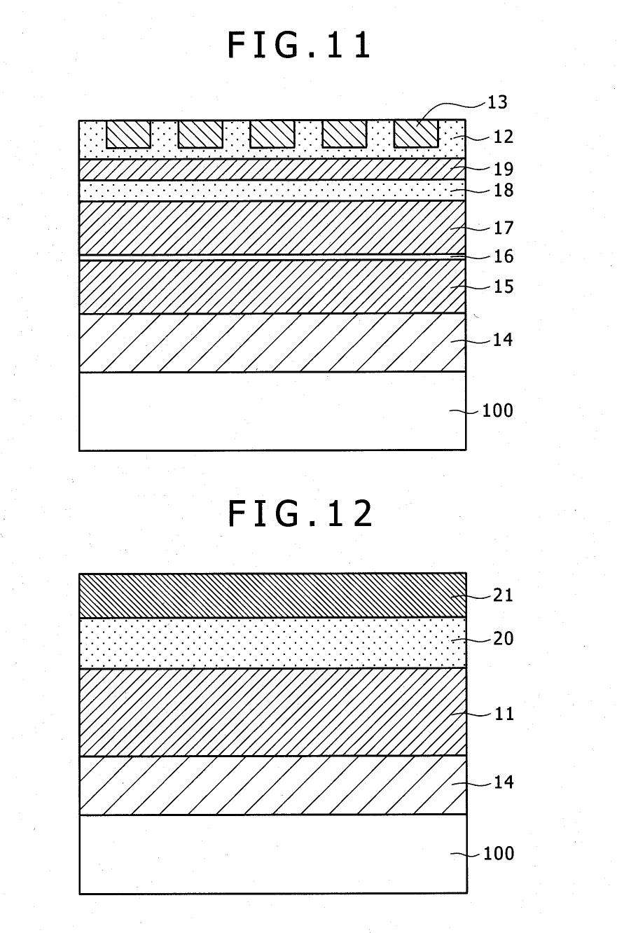

Further modification as shown in FIG. 11 is also possible. The modified one has the underlying layer 18 and the stabilizing layer 19, which are formed sequentially on the second soft magnetic layer 17. In this case, the underlying layer 12 on the stabilizing layer 19 functions as a magnetic coupling layer, and the resulting magnetic recording medium excels in thermal stability on account of anti-ferromagnetic coupling that occurs between the magnetic moment of the stabilizing layer 19 and the magnetic moment of the recording layer 13.

The underlying layer 18 may be coated with stabilizing layers and magnetic coupling layers of non-magnetic material which are alternately laminated.

The magnetic recording medium shown in FIG. 9 is produced by the process which is explained below with reference to FIGS. 12 to 15.

First, the substrate 100 is coated with the precoat layer 14 by plating, sputtering or CVD. On the precoat layer 14 is formed the soft magnetic layer 11 by plating, sputtering or CVD.

The underlying layer 20 is formed by epitaxial growth. The underlying layer 20 is coated with the photoresist 21 for patterning. The foregoing steps give rise to the layer structure shown in FIG. 12.

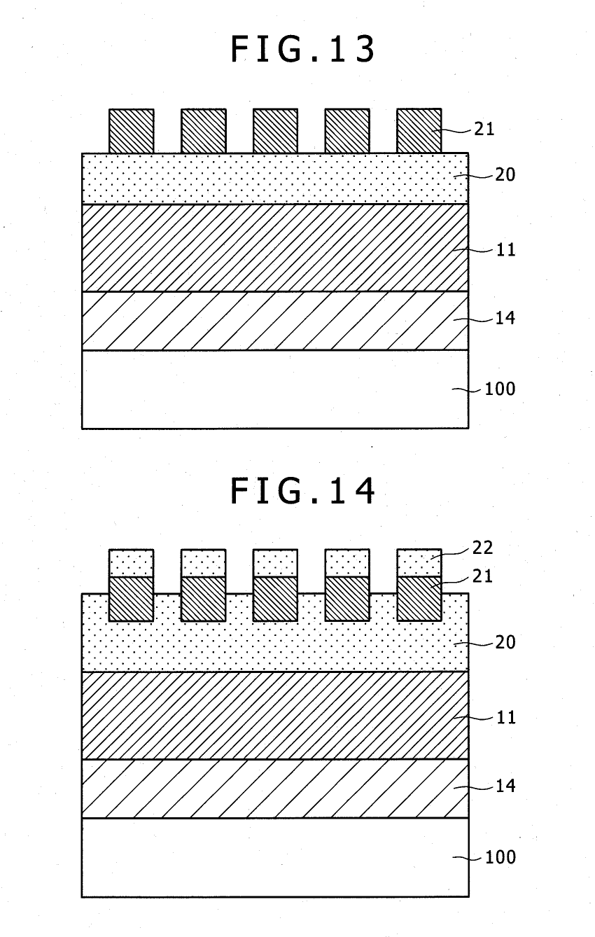

The photoresist 21 undergoes photolithography and subsequent development to form grooves, as shown in FIG. 13.

The thus formed grooves are filled with the same material as the underlying layer 20 by epitaxial growth, as shown in FIG. 14.

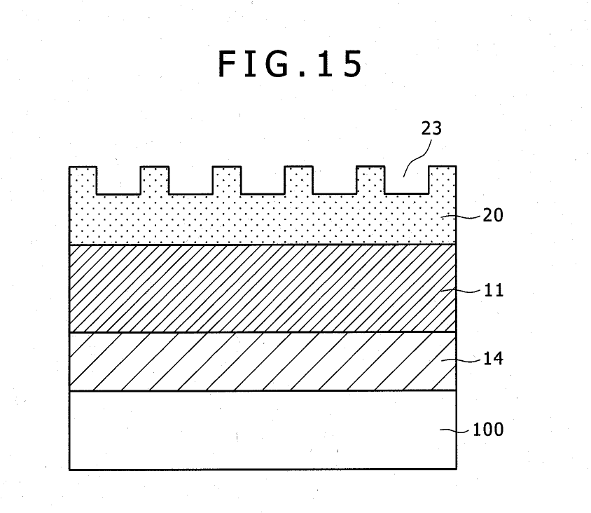

The photoresist 21 and the material 22 deposited thereon are removed all at once by dipping in a solvent such as acetone. This step forms the pits 23 (to be filled with a magnetic material), as shown in FIG. 15.

The pits 23 are filled with a magnetic material, and this step is followed by CMP for planarizing. In this way there is obtained the magnetic recording medium shown in FIG. 9.

In practical process, however, the magnetic recording medium shown in FIG. 9 is coated with an overcoat containing carbon and a lubricating film sequentially. Such additional films are omitted in this embodiment.

Thus there is obtained the magnetic recording medium which has good crystallinity and thermal stability and also has fairly uniform magnetic recording bits.

It should be understood by those skilled in the art that various modifications, combinations, sub-combinations and alterations may occur depending on design requirements and other factors insofar as they are within the scope of the appended claims or the equivalents thereof.

What is claimed is:

1. A dot-patterned structure composed of a first layer, which is continuous, and a second layer, which is discrete, wherein
said first layer is constructed of a thin film of crystalline structure and a layer integrally formed thereon by filling lithographically formed grooves with the same material as said thin film, and said second film is formed by filling the pits, which remain after removal of the photoresist used for lithography, with a material different from the material of said thin film.

2. The dot-patterned structure as defined in claim 1, wherein said first layer is formed by filling said lithographically formed grooves with the same material as said thin film by epitaxial growth.

3. The dot-patterned structure as defined in claim 2, wherein said second layer is formed by filling the pits, which remain after removal of the photoresist used for lithography, with a material different from the material of said thin film by epitaxial growth.

4. A method for producing a dot-patterned structure composed of a first layer, which is continuous, and a second layer, which is discrete, said method comprising the steps of
forming grooves by lithography in a thin film with crystalline structure,
filling said grooves with the same material as said thin film, thereby forming said first layer,
removing a photoresist used for lithography, thereby forming pits, and
filling the pits with a material different from the material of said thin film, thereby forming said second layer, which is discrete.

5. The method for producing a dot-patterned structure as defined in claim 4, wherein said first layer is formed by filling the lithographically formed grooves depthwise partly with the same material as said thin film, and said second layer is formed subsequently by filling the pits, which remain after removal of the photoresist used for lithography, with a material different from the material of said thin film.

6. The method for producing a dot-patterned structure as defined in claim 4, wherein said first layer is formed by filling with the same material as said thin film by epitaxial growth.

7. The method for producing a dot-patterned structure as defined in claim 4, wherein said first layer is formed by filling with the same material as said thin film by epitaxial growth, and said second layer is formed by removing the photoresist used for lithography in a solvent, thereby forming pits, and subsequently filling said pits with a material different from the material of said thin film by epitaxial growth.

8. A magnetic recording medium which comprises a substrate, an underlying layer, and a recording layer, which are arranged sequentially on top of the other, said recording layer being formed by the steps of forming grooves by lithography in said underlying layer, filling said grooves with the same material as said underlying layer, and filling pits, which remain after removal of the photoresist used for lithography, with a magnetic film.

9. The magnetic recording medium as defined in claim 8, wherein the grooves are filled with the same material as said underlying layer by epitaxial growth.

10. The magnetic recording medium as defined in claim 8, wherein the grooves are filled with the same material as said underlying layer by epitaxial growth and the magnetic film as the recording layer is also filled by epitaxial growth.

11. The magnetic recording medium as defined in claim 8, wherein said underlying layer is formed from a material containing any of Cr, W, and Mo, and said recording layer is formed from a material containing Co.

12. A method for producing a magnetic recording medium having a substrate and an underlying layer, said method comprising the steps of
forming grooves by lithography in said underlying layer,
filling said grooves with the same material as said underlying layer,
removing a photoresist used for lithography, thereby forming pits, and
filling said pits with a magnetic film as a recording layer.

13. The method for producing a magnetic recording medium as defined in claim 12, wherein the grooves formed by lithography are filled depthwise partly with the same material as said underlying layer, the photoresist used for lithography is removed to form pits, and the pits are filled with a magnetic film as said recording layer.

14. The method for producing a magnetic recording medium as defined in claim 12, wherein the grooves formed by lithography are filled with the same material as said underlying layer by epitaxial growth.

15. The method for producing a magnetic recording medium as defined in claim 12, wherein the grooves formed by lithography are filled with the same material as said underlying layer by epitaxial growth, and subsequently the photoresist used for lithography is removed in a solvent so as to form pits, and the pits are filled with a magnetic film as said recording layer by epitaxial growth.

16. The method for producing a magnetic recording medium as defined in claim 12, wherein said underlying layer is formed from a material containing any of Cr, W, and Mo, and said recording layer is formed from a material containing Co.

17. A magnetic recording medium which comprises a substrate, a soft magnetic layer, an underlying layer, and a recording layer, which are arranged sequentially on top of the other, said recording layer being formed by the steps of forming grooves by lithography in said underlying layer, filling said grooves with the same material as said underlying layer, and filling pits, which remain after removal of the photoresist used for lithography, with a magnetic film.

18. The magnetic recording medium as defined in claim 17, wherein said grooves formed by lithography in said underlying layer are filled with the same material as said underlying layer by epitaxial growth.

19. The magnetic recording medium as defined in claim 17, wherein said grooves formed by lithography in said underlying layer are filled with the same material as said underlying layer by epitaxial growth, and the pits formed by removal of the photoresist used for lithography are filled with a magnetic film as said recording layer by epitaxial growth.

20. The magnetic recording medium as defined in claim 17, wherein said underlying layer is formed from a material containing any of Ru, Os, and Re, and said recording layer is formed from a material containing Co.

21. A method for producing a magnetic recording medium which comprises the steps of
coating a substrate with a soft magnetic layer and an underlying layer sequentially,
treating said underlying layer by lithography to form grooves therein,
filling said grooves with the same material as said underlying layer,
removing a photoresist used for lithography, thereby forming pits, and
filling said pits with a magnetic film as a recording layer.

22. The method for producing a magnetic recording medium as defined in claim 21, wherein the grooves formed by lithography are filled depthwise partly with the same material as said underlying layer, the photoresist used for lithography is removed to form pits, and the pits are filled with a recording film as the recording layer.

23. The method for producing a magnetic recording medium as defined in claim 21, wherein the grooves formed by lithography in said underlying layer are filled with the same material as said underlying layer by epitaxial growth.

24. The method for producing a magnetic recording medium as defined in claim 21, wherein the grooves formed by lithography in said underlying layer are filled with the same material as said underlying layer by epitaxial growth, the photoresist used for lithography is removed in a solvent to form pits, and said pits are filled by epitaxial growth with a magnetic film as the recording layer.

25. The method for producing a magnetic recording medium as defined in claim 21, wherein said underlying layer is formed from a material containing any of Ru, Os, and Re, and said recording layer is formed from a material containing Co.
